(19) United States
(12) Patent Application Publication
(10) Pub. No.: US 2020/0126458 A1
(43) Pub. Date: Apr. 23, 2020

(54) FLEXIBLE DISPLAY DEVICE

(71) Applicant: Wuhan China Star Optoelectronics Technology Co., Ltd., Wuhan (CN)

(72) Inventor: Shiyuan XIAO, (US)

(73) Assignee: Wuhan China Star Optoelectronics Technology Co., Ltd., Wuhan (CN)

(21) Appl. No.: 16/319,341

(22) PCT Filed: Sep. 13, 2018
(86) PCT No.: PCT/CN2018/105483

§ 371 Date: Jan. 20, 2019

(30) Foreign Application Priority Data
Jul. 24, 2018 (CN) 201810822058.2

(51) Int. Cl. G09F 9/30; H01L 27/32; H05K 1/18; H05K 3/32

(52) U.S. Cl. CPC G09F 9/301; H01L 27/322; H05K 2201/10128; H05K 3/323; H05K 1/189

(57) ABSTRACT

A flexible display device is provided. The flexible display device includes a color filter substrate, an array substrate, and a flexible circuit board. One end of the array substrate is provided with a first array-substrate pad, a second array-substrate pad, and a via hole, wherein the first array-substrate pad is electrically connected with the via hole, the second array-substrate pad, and the flexible-circuit-board pad in order. Thus, an edge length of the flexible display device can be further shortened, so as to design the flexible display device to have a narrower frame.

### FIELD OF INVENTION

The present disclosure relates to a flexible display device, and more particularly to a flexible display device which shortens length of an array substrate for narrow frames.

### BACKGROUND OF INVENTION

With advancement of display technology, many display devices are developing towards having a narrow frame. However, because one end of the flexible display device needs to be connected with a flexible circuit board, it usually requires to be made longer, which is disadvantageous for a development direction towards narrow frames.

Refer to FIG. 1 and FIG. 2, wherein FIG. 1 is a schematic cross-sectional view of a conventional flexible display device, and FIG. 2 is a partial enlargement view of FIG. 1. As shown in FIG. 1, a conventional flexible display device 10 includes a color filter substrate 11, an array substrate 12, and a flexible circuit board 13.

In detail, as shown in FIG. 2, the array substrate 12 is attached with the color filter substrate 11, wherein one end of the array substrate 12 is provided with an array-substrate pad 12a, and the array-substrate pad 12a is disposed on a surface facing the color filter substrate 11. Furthermore, one end of the flexible circuit board 13 is provided with a flexible-circuit-board pad 13a, and the flexible-circuit-board pad 13a is attached and electrically connected with the array-substrate pad 12a.

However, in order to achieve that the flexible-circuit-board pad 13a is attached and electrically connected with the array-substrate pad 12a, the array substrate 12 is requires to be longer in length compared with a length of the color filter substrate 11, so that it is disadvantageous for a development direction towards narrow frames.

Hence, it is necessary to provide an improved flexible display device to solve the above-mentioned technical problems.

### SUMMARY OF INVENTION

A primary object of the present disclosure is to provide a flexible display device, which further shortens an edge length of the flexible display device, so as to design the flexible display device for narrower frames.

To achieve the above object, the present disclosure provides a flexible display device, which comprises: a color filter substrate; an array substrate attached with the color filter substrate, wherein one end of the array substrate is provided with a first array-substrate pad, a second array-substrate pad, and a via hole; the first array-substrate pad is disposed on a surface of the array substrate facing the color filter substrate, and the first array-substrate pad is attached to the color filter substrate; the second array-substrate pad is disposed on another surface of the array substrate; and the via hole is formed in the array substrate and pass through the array substrate so as to connect the first array-substrate pad to the second array-substrate pad; and a flexible circuit board having a flexible-circuit-board pad at one end thereof, wherein the flexible-circuit-board pad is electrically connected with the second array-substrate pad, and one end of the flexible circuit board is attached to the array substrate, so that the first array-substrate pad is electrically connected with the via hole, the second array-substrate pad, and the flexible-circuit-board pad in order.

In one embodiment of the present disclosure, the flexible-circuit-board pad is electrically connected with the second array-substrate pad by an attachment method.

In one embodiment of the present disclosure, the flexible-circuit-board pad is electrically connected with the second array-substrate pad by an anisotropic conductive film, using an attachment method.

In one embodiment of the present disclosure, the flexible-circuit-board pad is electrically connected with the second array-substrate pad by a wire bonding method.

In one embodiment of the present disclosure, relative to a position of the via hole, an extension direction of the first array-substrate pad is identical with an extension direction of the second array-substrate pad.

In one embodiment of the present disclosure, relative to a position of the via hole, an extension direction of the first array-substrate pad is opposite to an extension direction of the second array-substrate pad.

In one embodiment of the present disclosure, the color filter substrate and the array substrate are made of a flexible organic material.

In one embodiment of the present disclosure, the color filter substrate and the array substrate are made of polyimide material.

In the present disclosure, compared with a conventional flexible display device, a length of the array substrate of the present disclosure does not need to be set larger than a length of the color filter substrate, Thus, an edge length of the flexible display device can be further shortened, so as to design the flexible display device for narrower frames.

To achieve the above object, the present disclosure further provides a flexible display device, which comprises: a color filter substrate; an array substrate attached with the color filter substrate, wherein one end of the array substrate is provided with a first array-substrate pad, a second array-substrate pad, and a via hole; the first array-substrate pad is disposed on a surface of the array substrate facing the color filter substrate; the second array-substrate pad is disposed on another surface of the array substrate; and the via hole is formed in the array substrate and pass through the array substrate so as to connect the first array-substrate pad to the second array-substrate pad; and a flexible circuit board having a flexible-circuit-board pad at one end thereof, wherein the flexible-circuit-board pad is electrically connected with the second array-substrate pad, so that the first array-substrate pad is electrically connected with the via hole, the second array-substrate pad, and the flexible-circuit-board pad in order.

In one embodiment of the present disclosure, the first array-substrate pad is attached to the color filter substrate.

In one embodiment of the present disclosure, one end of the flexible circuit board is attached to the array substrate.

In one embodiment of the present disclosure, the flexible-circuit-board pad is electrically connected with the second array-substrate pad by an attachment method.

In one embodiment of the present disclosure, the flexible-circuit-board pad is electrically connected with the second array-substrate pad by an anisotropic conductive film, using an attachment method.

In one embodiment of the present disclosure, the flexible-circuit-board pad is electrically connected with the second array-substrate pad by a wire bonding method.

In one embodiment of the present disclosure, relative to a position of the via hole, an extension direction of the first array-substrate pad is identical with an extension direction of the second array-substrate pad.

In one embodiment of the present disclosure, relative to a position of the via hole, an extension direction of the first array-substrate pad is opposite to an extension direction of the second array-substrate pad.

In one embodiment of the present disclosure, the color filter substrate and the array substrate are made of a flexible organic material.

In one embodiment of the present disclosure, the color filter substrate and the array substrate are made of polyimide material.

In the present disclosure, compared with a conventional flexible display device, a length of the array substrate of the present disclosure does not need to be set larger than a length of the color filter substrate, Thus, an edge length of the flexible display device can be further shortened, so as to design the flexible display device for narrower frames.

### DESCRIPTION OF DRAWINGS

FIG. 1 is a schematic cross-sectional view of a conventional flexible display device.

FIG. 2 is a partial enlargement view of FIG. 1.

FIG. 3 is a schematic cross-sectional view of a flexible display device of the present disclosure.

FIG. 4 is a partial enlargement view of FIG. 3.

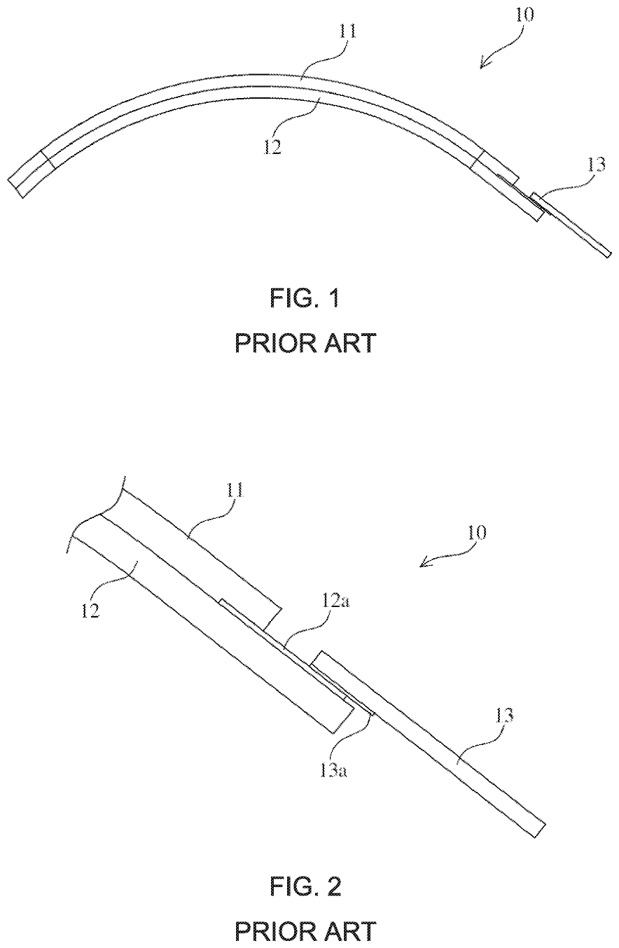

### DETAILED DESCRIPTION OF PREFERRED EMBODIMENTS

The foregoing objects, features, and advantages adopted by the present disclosure can be best understood by referring to the following detailed description of the preferred embodiments and the accompanying drawings. Furthermore, the directional terms described in the present disclosure, such as upper, lower, front, rear, left, right, inside, outer, side, etc., are only directions with reference to the accompanying drawings, so that the used directional terms are used to describe and understand the present disclosure, but the present disclosure is not limited thereto. In the drawings, units with similar structures use the same numerals.

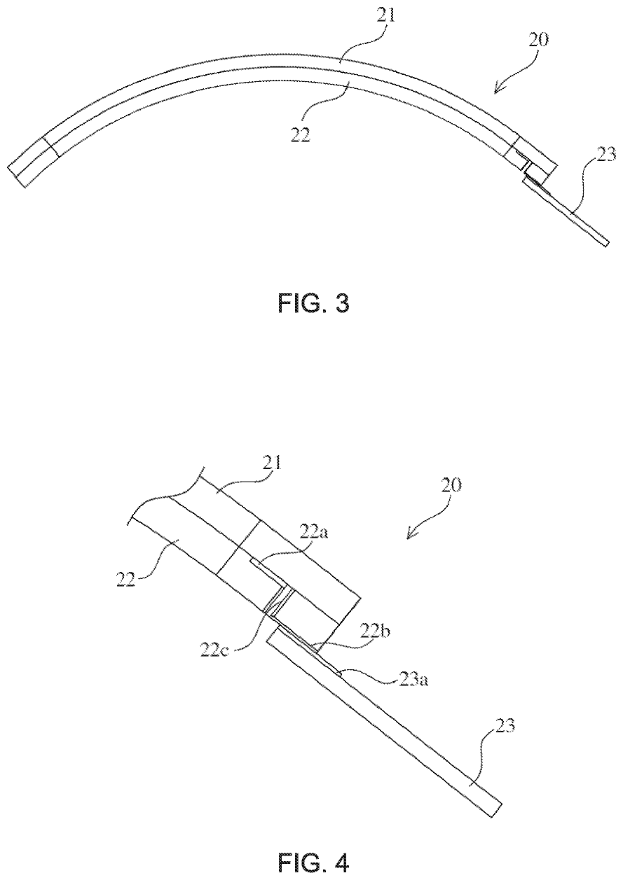

Refer to FIG. 3 and FIG. 4, wherein FIG. 3 is a schematic cross-sectional view of a flexible display device of the present disclosure, and FIG. 4 is a partial enlargement view of FIG. 3. As shown in FIG. 3, a flexible display device 20 of the present disclosure includes a color filter substrate 21, an array substrate 22, and a flexible circuit board 23.

Preferably, the first array-substrate pad is attached to the color filter substrate.

Preferably, the color filter substrate 21 and the array substrate 22 are made of a flexible organic material, for example, a polyimide (PI) material.

In detail, as shown in FIG. 4, the array substrate 22 is attached with the color filter substrate 21, wherein one end of the array substrate 22 is provided with a first array-substrate pad 22a, a second array-substrate pad 22b, and a via hole 22c. The first array-substrate pad 22a is disposed on a surface facing the color filter substrate 21. The second array-substrate pad 22b is disposed on another surface of the array substrate 22. The via hole 22c is formed in the array substrate 22 and pass through the array substrate 22 so as to connect the first array-substrate pad 22a to the second array-substrate pad 22b, respectively.

Furthermore, one end of the flexible circuit board 23 is provided with a flexible-circuit-board pad 23a, and the flexible-circuit-board pad 23a is electrically connected with the second array-substrate pad 22b.

In this embodiment, one end of the flexible circuit board 23 is attached to the array substrate 22.

In this embodiment, the flexible-circuit-board pad 23a and the second array-substrate pad 22b are electrically connected by an attachment method. Preferably, the flexible-circuit-board pad 23a and the second array-substrate pad 22b are attached by an anisotropic conductive film (ACF). However, in another possible embodiment of the present disclosure, the flexible-circuit-board pad 23a and the second array-substrate pad 22b may be electrically connected by a wire bonding method.

Furthermore, in the present embodiment, relative to a position of the via hole 22c, an extension direction of the first array-substrate pad 22a is identical with an extension direction of the second array-substrate pad 22b. However, in another possible embodiment of the present disclosure, relative to a position of the via hole 22c, an extension direction of the first array-substrate pad 22a is opposite to an extension direction of the second array-substrate pad 22b.

As mentioned above, in one embodiment of the present disclosure, one end of the array substrate 22 is provided with a first array-substrate pad 22a, a second array-substrate pad 22b, and a via hole 22c. The via hole 22c passes through the array substrate 22, and connects with the first array-substrate pad 22a and the second array-substrate pad 22b, respectively. Furthermore, one end of the flexible circuit board 23 is provided with a flexible-circuit-board pad 23a, and the flexible-circuit-board pad 23a is electrically connected with the second array-substrate pad 22b. Thus, the first array-substrate pad 22a is electrically connected with the via hole 22c, the second array-substrate pad 22b, and the flexible-circuit-board pad 23a in order.

Compared with a conventional flexible display device, a length of the array substrate 22 of the present disclosure does not need to be made longer than a length of the color filter substrate 21, Thus, an edge length of the flexible display device 20 can be further shortened, so as to design the flexible display device 20 to have a narrower frame.

The present disclosure has been described with preferred embodiments thereof and it is understood that many changes and modifications to the described embodiment can be carried out without departing from the scope and the spirit of the invention that is intended to be limited only by the appended claims.

What is claimed is:

1. A flexible display device, comprising:
a color filter substrate;
an array substrate attached with the color filter substrate, wherein one end of the array substrate is provided with a first array-substrate pad, a second array-substrate pad, and a via hole; the first array-substrate pad is disposed on a surface of the array substrate facing the color filter substrate, and the first array-substrate pad is attached to the color filter substrate; the second array-substrate pad is disposed on another surface of the array substrate; and the via hole is formed in the array substrate and passes through the array substrate so as to connect the first array-substrate pad to the second array-substrate pad; and
a flexible circuit board having a flexible-circuit-board pad at one end thereof, wherein the flexible-circuit-board pad is electrically connected with the second array-substrate pad, and one end of the flexible circuit board is attached to the array substrate, so that the first array-substrate pad is electrically connected with the via hole, the second array-substrate pad, and the flexible-circuit-board pad in order.

2. The flexible display device according to claim 1, wherein the flexible-circuit-board pad is electrically connected with the second array-substrate pad by an attachment method.

3. The flexible display device according to claim 2, wherein the flexible-circuit-board pad is electrically connected with the second array-substrate pad by an anisotropic conductive film, using an attachment method.

4. The flexible display device according to claim 1, wherein the flexible-circuit-board pad is electrically connected with the second array-substrate pad by a wire bonding method.

5. The flexible display device according to claim 1, wherein relative to a position of the via hole, an extension direction of the first array-substrate pad is identical with an extension direction of the second array-substrate pad.

6. The flexible display device according to claim 1, wherein relative to a position of the via hole, an extension direction of the first array-substrate pad is opposite to an extension direction of the second array-substrate pad.

7. The flexible display device according to claim 1, wherein the color filter substrate and the array substrate are made of a flexible organic material.

8. The flexible display device according to claim 7, wherein the color filter substrate and the array substrate are made of polyimide material.

9. A flexible display device, comprising:
a color filter substrate;
an array substrate attached with the color filter substrate, wherein one end of the array substrate is provided with a first array-substrate pad, a second array-substrate pad, and a via hole; the first array-substrate pad is disposed on a surface of the array substrate facing the color filter substrate; the second array-substrate pad is disposed on another surface of the array substrate; and the via hole is formed in the array substrate and pass through the array substrate so as to connect the first array-substrate pad to the second array-substrate pad; and
a flexible circuit board having a flexible-circuit-board pad at one end thereof, wherein the flexible-circuit-board pad is electrically connected with the second array-substrate pad, so that the first array-substrate pad is electrically connected with the via hole, the second array-substrate pad, and the flexible-circuit-board pad in order.

10. The flexible display device according to claim 9, wherein the first array-substrate pad is attached to the color filter substrate.

11. The flexible display device according to claim 9, wherein one end of the flexible circuit board is attached to the array substrate.

12. The flexible display device according to claim 11, wherein the flexible-circuit-board pad is electrically connected with the second array-substrate pad by an attachment method.

13. The flexible display device according to claim 12, wherein the flexible-circuit-board pad is electrically connected with the second array-substrate pad by an anisotropic conductive film, using an attachment method.

14. The flexible display device according to claim 11, wherein the flexible-circuit-board pad is electrically connected with the second array-substrate pad by a wire bonding method.

15. The flexible display device according to claim 9, wherein relative to a position of the via hole, an extension direction of the first array-substrate pad is identical with an extension direction of the second array-substrate pad.

16. The flexible display device according to claim 9, wherein relative to a position of the via hole, an extension direction of the first array-substrate pad is opposite to an extension direction of the second array-substrate pad.

17. The flexible display device according to claim 9, wherein the color filter substrate and the array substrate are made of a flexible organic material.

18. The flexible display device according to claim 17, wherein the color filter substrate and the array substrate are made of polyimide material.
